(19) United States
(12) Patent Application Publication
(10) Pub. No.: US 2006/0267158 A1
(43) Pub. Date: Nov. 30, 2006

(54) Semiconductor memory apparatus having improved charge retention as a result of bit line shielding

(76) Inventor: Rolf Weis, Dresden (DE)

Correspondence Address: DICKE, BILLIG & CZAJA, P.L.L.C., FIFTH STREET TOWERS, 100 SOUTH FIFTH STREET, SUITE 2250, MINNEAPOLIS, MN, 55402, US

(21) Appl. No.: 11/431,808

(22) Filed: May 10, 2006

(30) Foreign Application Priority Data
May 11, 2005 (DE) 10 2005021825.3

(51) Int. Cl. H01L 23/552

(52) U.S. Cl. 257/659

(57) ABSTRACT

A semiconductor memory apparatus having bit lines for driving a selection transistor with a storage capacitor is disclosed. In one embodiment, shielding between adjacent bit lines by means of a conductive shielding device results in a reduction in the bit line-bit line coupling and makes it possible to improve the charge retention time even when avoiding concepts which use chip area such as a bit line twist.

### CROSS-REFERENCE TO RELATED APPLICATIONS

This Utility Patent Application claims priority to German Patent Application No. DE 10 2005021825.3, filed on May 11, 2005, which is incorporated herein by reference.

### FIELD OF THE INVENTION

The invention relates to a semiconductor memory apparatus and to a method for producing a conductive shielding device of the semiconductor memory apparatus.

### BACKGROUND

Semiconductor memory apparatuses such as DRAMs (Dynamic Random Access Memories) use a charge, which can be stored/read in a capacitor, to write/read information bits. Trench capacitors which are formed in a semiconductor substrate and stack capacitors which are formed above the semiconductor substrate are preferably used as the capacitor in a semiconductor memory cell. DRAMs having trench capacitors need a capacitance of approximately 35 fF per memory cell for proper memory operation, whereas DRAMs having stack capacitors require a capacitance of only approximately 25 fF per memory cell. These differences in the capacitance required, which depend on the embodiment of the capacitor, can be attributed to the fact that an overall bit line capacitance and bit line-bit line coupling between DRAMs having a trench capacitor and DRAMs having a stack capacitor have different magnitudes, thus entailing different signal shapes.

In order to provide a sense amplifier with signals having similar signal amplitudes, irrespective of the design of the capacitor as a trench or stack capacitor, the capacitances of DRAMs having trench capacitors are designed to be larger than those of DRAMs having stack capacitors. In the case of a DRAM having stack capacitors, the bit lines are separated from one another by a memory node contact which connects the selection transistor to the capacitor, thus entailing, on the one hand, a larger overall bit line capacitance but, on the other hand, resulting in shielding of adjacent bit lines. In the case of a DRAM having a trench capacitor, there is no need for a memory node contact which is guided by the bit lines on account of the capacitor which is implemented in the semiconductor substrate.

As component dimensions were reduced in order to increase the integration density, the capacitance of the trench capacitor was retained, during the transition to subsequent memory generations, by reducing the thickness of a dielectric of the capacitor. Such a further reduction in the thickness of the dielectric could not be retained during the transition to memory generations with ground rules beyond 100 nm on account of the occurrence of tunneling currents. It was thus necessary to provide concepts for increasing capacitor surfaces further and to provide high-k materials in order to compensate for the loss of area of the capacitor when reducing the sizes of the structures as regards the capacitance values which can be achieved.

A charge retention time of the capacitor, which concomitantly determines a refresh time, fundamentally depends, inter alia, on the overall bit line capacitance and the bit line-bit line coupling. In the case of DRAMs having trench capacitors, it is customary to reduce the bit line-bit line coupling using a so-called bit line twist. In this case, the bit lines are respectively connected in pairs to a sense amplifier, in which case, in contrast to bit lines which merely run parallel to one another when there is no twist, two bit lines which are connected to a sense amplifier as a bit line pair are alternately twisted and not twisted from bit line pair to bit line pair. Two bit lines which run parallel to one another are twisted, for example, by crossing the two bit lines with the aid of further metal planes and then arranging them such that they run parallel to one another again. This makes it possible to reduce the bit line-bit line coupling. However, such a bit line twist entails the disadvantage that such twisting of the bit lines takes up chip area, thus resulting in an increase in the amount of area required for each semiconductor memory apparatus and thus in increased costs.

For these and other reasons there is need for the present invention.

### SUMMARY

The invention relates to a semiconductor memory apparatus having bit lines for driving a selection transistor with a storage capacitor. In one embodiment, shielding between adjacent bit lines by means of a conductive shielding device results in a reduction in the bit line-bit line coupling and makes it possible to improve the charge retention time.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

Further features and advantages of the invention become apparent from the following description of preferred embodiments with reference to the figures, in which:

FIGS. 1A and B illustrate a cross-sectional view and a plan view of a first embodiment of a semiconductor memory apparatus having a conductive shielding device according to the invention.

FIGS. 2A to 7 illustrate diagrammatic cross-sectional views and plan views at various process stages during the production of the first embodiment.

FIGS. 8A and B illustrate a diagrammatic cross-sectional view and a plan view of a second embodiment of the semiconductor memory apparatus according to the invention.

FIGS. 9A and B illustrate a diagrammatic cross-sectional view and a plan view of a third embodiment of a semiconductor memory apparatus having a conductive shielding device according to the invention.

FIGS. 10A and B illustrate a diagrammatic cross-sectional view and a plan view of a fourth embodiment of a semiconductor memory apparatus having a conductive shielding device according to the invention.

FIGS. 11 and 12 illustrate diagrammatic plan views of a cell array of a semiconductor memory apparatus having a conductive shielding device with contact regions for contact-connecting the conductive shielding device.

FIG. 13 illustrates a plan view of a cell array of a semiconductor memory apparatus having a conductive shielding device and without a bit line twist.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

The present invention provides a semiconductor memory apparatus having improved charge retention whilst avoiding the problems described at the outset as well as a method for producing the apparatus.

In one embodiment, the invention provides a semiconductor memory apparatus having a plurality of bit lines which are arranged next to one another and run above a semiconductor substrate, in particular a silicon wafer, as well as an insulation structure which at least laterally adjoins the bit lines. In this case, provision is made of a respective conductive shielding device which is formed between two bit lines (which are arranged next to one another), is at a distance from the bit lines and at least partially adjoins the insulation structure. The bit lines are each used to connect a selection transistor, which can be switched on and off using a gate electrode that is connected to a word line, in order to charge/discharge a storage capacitor that is connected to the selection transistor. The charge stored in the storage capacitor characterizes a memory state, i.e. the presence of a logic “1” or “0”, of a memory cell which comprises the selection transistor and the storage capacitor. The shielding device, which can be formed in a DRAM having a trench capacitor, on the one hand increases the overall bit line capacitance and on the other hand reduces the bit line-bit line coupling. Charge retention in the storage capacitor, which depends both on the overall bit line capacitance and on the bit line-bit line coupling, can be improved by the reduction in the bit line-bit line coupling, which promotes charge retention, overcompensating for the increase in the overall bit line capacitance, which impairs charge retention. It shall be pointed out that charge retention and the detection of the latter are based on a dynamic operation, with the result that charge-reversal operations of capacitances are particularly relevant. The detection of the charge using a sense amplifier is thus not solely determined by leakage currents.

The conductive shielding device has a plurality of shielding elements. The latter may be arranged, for example, in such a manner that a plurality of the shielding elements are located along a horizontal connecting line between two bit lines which are arranged next to one another. It is likewise possible to arrange the conductive shielding elements in such a manner that one respective shielding element is formed along a horizontal connecting line between two bit lines which are arranged next to one another, the shielding elements being vertically stacked above one another, however, with the result that horizontal connecting lines between two bit lines which are arranged next to one another cross different shielding elements depending on their height.

The conductive shielding device has at least one metal and/or at least one doped semiconductor material. The selection of a suitable metal is fundamentally determined by process integration, aluminum, copper, tungsten, titanium or a combination of these preferably being suitable as the metal. It is likewise possible to form the conductive shielding device or parts thereof using metal silicides such as TiSi2, MoSi2, WSi2, CoSi2 or a combination of these. Alternatively or in addition, the conductive shielding device or parts thereof may be in the form of a doped semiconductor material. Polysilicon whose conductivity is set by doping with, for instance, phosphorus for N-type conductivity or boron for P-type conductivity is particularly suitable as the semiconductor material. It is likewise possible to form the conductive shielding device or parts thereof in the form of one or more metal nitrides, preferably TiN.

In one embodiment, the conductive shielding device is formed such that it is at least as close to the semiconductor substrate as the bit lines in an intermediate dielectric which is below the bit lines. The intermediate dielectric insulates the bit lines and the conductive shielding element from the semiconductor substrate and is advantageously in the form of silicon oxide, particularly TEOS (tetraethylorthosilane). If the conductive shielding device is formed such that it is closer to the semiconductor substrate than the bit lines, a vertical distance from an underside of the conductive shielding device through the intermediate dielectric to a surface of the semiconductor substrate is shorter than a corresponding distance from an underside of the bit lines. Consequently, bit line-bit line coupling which is caused through the intermediate dielectric is reduced. It shall be pointed out that an underside of the shielding device may also be slightly above an underside of the bit line depending on the process control when producing the insulation structure.

In one embodiment, the insulation structure is formed such that it is closer to the semiconductor substrate than the bit lines. Consequently, the vertical distance from an underside of the insulation structure through the intermediate dielectric to the surface of the semiconductor substrate is shorter than a corresponding distance from the underside of the bit lines to the surface of the semiconductor substrate. Apart from possible advantages in terms of process technology, such an embodiment is particularly advantageous if the intermediate dielectric has a dielectric constant that is greater than that of the insulation structure.

In another embodiment, the insulation structure adjoins an underside of the conductive shielding device. As in the case of the insulation structure which is formed such that it is closer to the substrate than the bit lines, such a configuration of the insulation structure around the underside of the conductive shielding device is particularly advantageous if the dielectric constant of the intermediate dielectric is greater than that of the insulation structure. Reasons from the point of view of manufacturing, for example saving process steps, may likewise be in favor of such an embodiment.

In one embodiment, the insulation structure is formed as a contiguous insulation structure in a cell array, i.e. a region containing the memory cells. Therefore, the insulation structure not only laterally adjoins the bit lines as a spacer but is also formed above the bit lines such that it adjoins a part of the intermediate dielectric, which is between adjacent bit lines. The insulation structure thus covers the cell array of the semiconductor memory apparatus.

A protective layer is formed on each of the bit lines. The protective layer may be, for example, in the form of an oxide hard mask, in particular a mask comprising TEOS, or may have one or more materials which are suitable as an etching protective layer for patterning the bit lines.

In one embodiment, the conductive shielding device is formed such that it is at least as far away from the semiconductor substrate as the bit lines. If the conductive shielding device is formed such that it is further away than the bit lines, the vertical distance from the surface of the semiconductor substrate to a top side of the shielding device is longer than a corresponding distance from the surface of the semiconductor substrate to a top side of the bit lines. This embodiment results, in particular, in a reduction in that part of the bit line-bit line coupling which can be attributed to coupling between adjacent bit lines via dielectric layers, for instance of intermetal oxides (IMOX), which are formed above the bit lines.

The shielding device is formed above the bit lines and such that it covers the cell array. In this case, the shielding device which is formed above the bit line may be contiguous with the shielding device which is formed between the bit lines. This embodiment is particularly suitable for reducing that part of the bit line-bit line coupling which can be attributed to a dielectric layer which is formed above the bit lines.

The insulation structure adjoins the conductive shielding device. If the insulation structure has a lower dielectric constant than a dielectric layer that is formed above the bit lines, this embodiment is suitable for reducing the bit line-bit line capacitance further.

The conductive shielding device can be electrically contact-connected in an edge region of the cell array of the semiconductor memory apparatus. In this case, the shielding device is preferably connected to a constant potential in order to achieve improved charge retention by suitably setting the bit line-bit line capacitance and the overall bit line capacitance. In one embodiment in regards to the reduction in leakage currents, as the constant potential, an equalize voltage VBLEQ is selected, which usually corresponds to half a maximum bit line voltage Vblh, i.e. Vblh/2.

According to one embodiment of the invention, a method for producing a conductive shielding device for reducing the capacitive coupling between adjacent bit lines of a semiconductor memory apparatus includes the method of applying a metal layer to a preprocessed semiconductor substrate, applying a protective layer to the metal layer, patterning the protective layer in order to define the bit lines which are to be formed in the metal layer, forming the bit lines by removing the metal layer in regions which are not covered by the protective layer, applying an insulation structure in order to cover the protective layer, the bit lines and that region of the intermediate dielectric which is exposed between the bit lines, applying a conductive shielding device to the insulation structure, applying a protective mask to the conductive shielding device in a cell array region of the semiconductor memory, and removing the conductive shielding device outside the cell array in the region which is not a cell array. The protective layer thus provides etching protection for the cell array. A resist or else a layer that is suitable as etching protection may be used as the protective layer depending on the etching.

The preprocessed semiconductor substrate has, for example, an applied intermediate dielectric. The metal layer produced on the preprocessed semiconductor substrate contains aluminum, tungsten or copper or a combination of these, to which silicon may be optionally additionally added. The materials are selected taking into account requirements regarding conductivity, spiking and electromigration. The metal layer may be formed with the aid of sputtering, PVD (physical vapor deposition), CVD (chemical vapor deposition), ECD (electro-chemical deposition) or else PNLD (pulsed nuclear layer deposition) depending on the material system selected. In order to define the bit lines which are to be formed in the metal layer, the protective layer is lithographically patterned and the metal layer is selectively removed by etching. The insulation structure is realized as silicon oxide, in particular TEOS, and is conformally deposited using a CVD (chemical vapor deposition) method, in particular an LPCVD (low pressure CVD) method. It is likewise possible to form the insulation structure with one or more materials which differ from silicon oxide, for instance silicon nitride or low-k materials. Depending on the material composition of the conductive shielding device, the latter may be produced using methods such as PVD by evaporating and sputtering metals or CVD in order to deposit tungsten or polysilicon, for example, or using ECD in order to produce copper. A protective mask that covers a cell array of the semiconductor memory apparatus protects the conductive shielding device in this region when etching the same outside the cell array in the region which is not a cell array, for instance in a support region having drive and read circuit blocks.

In one embodiment, after the bit lines have been formed and before the insulation structure is formed, a part of an intermediate dielectric is removed, which is below the metal layer that has been removed. An etching step is suitable for this purpose. Removing a part of the intermediate dielectric makes it possible to form the insulation structure such that it is lower than the bit lines, thus making it possible, for example, for the insulation structure to adjoin the shielding device from below even though the shielding device is formed such that it is at least as close to the surface of the semiconductor substrate as the bit lines.

After the insulation structure has been applied and before the conductive shielding device is applied, extended spacer etching is effected in order to remove the insulation structure above the protective layer and in parts of a base region which adjoins the intermediate dielectric, so that spacers which adjoin side walls of the bit lines are produced. A part of the intermediate dielectric below the base region is additionally removed. Additionally removing a part of the intermediate dielectric makes it possible to form a conductive shielding device which reaches further in the direction of the semiconductor substrate than the bit lines and the insulation structure.

After the conductive shielding device has been applied and before the protective mask is applied, a covering layer is applied to the conductive shielding device. Such a covering layer which may comprise polysilicon, for example, makes it possible, for example, to fill gaps between bit lines that are arranged next to one another within the conductive shielding device, which gaps are caused by CD fluctuations (fluctuations in a critical dimension) when patterning the metal.

In one embodiment, the conductive shielding device is partially removed again, a part which is formed between the bit lines being retained and a part which is formed above the bit lines being lost. An etching process is suitable for this purpose. Removing the shielding device above the bit lines is particularly suitable if the charge retention time in the storage capacitor cannot be improved, on account of the increase in the overall bit line capacitance compared with the reduction in the bit line-bit line coupling, when the conductive shielding device is formed above the bit lines.

An insulation covering can be applied after the conductive shielding device has been removed outside the cell array. The insulation covering may be in the form of a TEOS layer, for example.

The explanations below are used to understand the effect of the overall bit line capacitance and the bit line-bit line coupling on a charge retention time Tret. This is given by:

$$Tret = \frac{Cdt}{Ileak} [ ( Vblh \cdot Pw - Vbleq ) - \frac{Vsa}{Pr} \cdot \frac{Cdt + {Cbl}^{′}}{Cdt \cdot ( 1 - \frac{Cblbl}{{Cbl}^{′}} )} ]$$

where Cdt is the storage capacitance, Ileak is the leakage current of a memory cell, Vblh is the maximum voltage of a bit line, Pw is the writing part, Vbleq is the equalize voltage, Vsa is the minimum read signal for correct evaluation, Pr is the reading part, Cbl′=Cbl+2Cblbl, Cbl is the overall bit line capacitance and Cblbl is the unilateral bit line-bit line coupling capacitance. In order to explain the effect of a conductive shielding device on the charge retention time, the text below uses a semiconductor memory apparatus both with and without a shielding device with reference to exemplary values of the parameters which are relevant to determining Tret. In the case of the semiconductor memory apparatus without a shielding device, where Cdt =35 fF, Cbl =110 fF, Cblbl=40 fF, Cbl′=190 fF, it follows that

$$Tret ∝ Cdt \cdot X - Y \cdot \frac{( Cdt + {Cbl}^{′} )}{( Cdt \cdot ( 1 - Cblbl / {Cbl}^{′} ) )} = 35 \cdot X - Y \cdot ( 35 + 190 ) / ( 35 \cdot ( 1 - 40 / 190 ) ) = 35 \cdot X - Y \cdot 8.24 .$$

The parameters X and Y in the above equation contain parameters of the semiconductor memory apparatus which remain constant when a conductive shielding device is inserted. In the case of the semiconductor memory apparatus with a conductive shielding device, Cdt=35 fF, Cbl=147 fF, Cblbl=15 fF and Cbl′=187 fF. It thus follows, for the charge retention time when a conductive shielding device is present, that

$$Tret ∝ Cdt \cdot X - Y \cdot \frac{( Cdt + {Cbl}^{′} )}{( Cdt \cdot ( 1 - Cblbl / {Cbl}^{′} ) )} = 35 \cdot X - Y \cdot ( 35 + 187 ) / ( 35 \cdot ( 1 - 15 / 187 ) ) = 35 \cdot X - Y \cdot 6.89 .$$

The conductive shielding device results in an increase in the overall bit line capacitance Cbl and in a reduction in the unilateral bit line-bit line coupling capacitance Cblbl. Despite the increase in the overall bit line capacitance Cbl, it is possible to increase the charge retention time since Cbl′ remains virtually constant with the aid of the above exemplary parameters, and the expression (1−Cblbl/Cbl′) decreases on account of the decreasing unilateral bit line-bit line coupling capacitance Cblbl and the virtually constant expression Cbl′. However, the reduction in the last-mentioned expression, caused by the decrease in the bit line-bit line coupling on account of the conductive shielding device, results in an increase in the charge retention time Tret. It is consequently possible, despite the increase in the overall bit line capacitance when the conductive shielding device is inserted, to increase the charge retention time Tret by reducing the unilateral bit line-bit line coupling capacitance Cblbl.

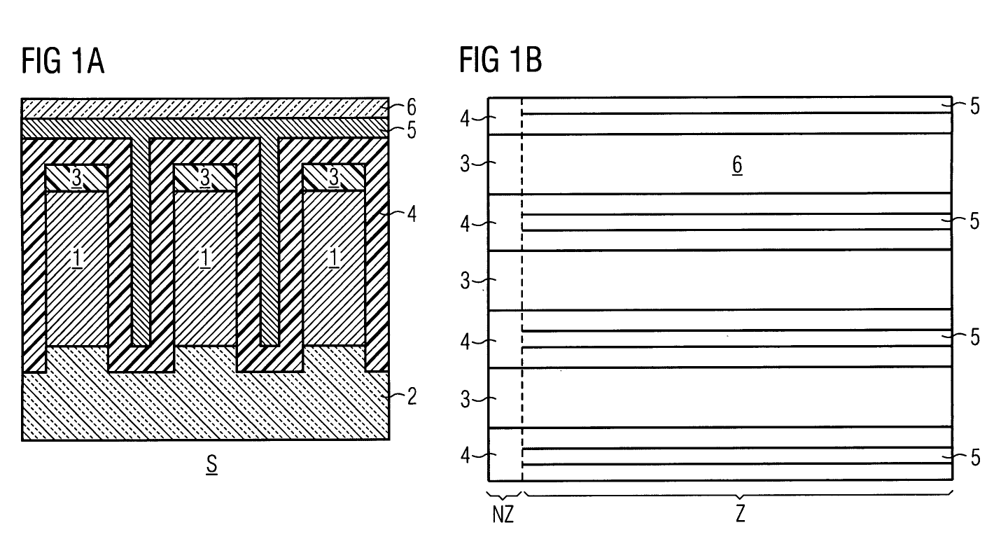

FIG. 1A illustrates a diagrammatic cross-sectional view of bit lines 1, which are arranged next to one another, of a semiconductor memory apparatus, in particular a DRAM. It shall be pointed out that for clarity only one part of the semiconductor memory apparatus, in particular in the region of the bit lines 1, is illustrated. Bit lines 1 are used to connect a selection transistor of a memory cell having a storage capacitor, in particular a DRAM memory cell, to a sense amplifier (not illustrated). The bit lines 1 are routed above an intermediate dielectric 2 which is formed on a semiconductor substrate S (S is shown only in FIG. 1A as representative of further cross-sectional views). A protective layer 3, for example a patterned TEOS, lies on the bit lines 1. An insulation structure 4, for example a TEOS, adjoins the bit lines 1, a part of the intermediate dielectric 2, which is formed between the bit lines 1, and the protective layer 3. The insulation structure 4 is routed within openings in the intermediate dielectric 2, which are formed between the bit lines 1, for which reason the insulation structure 4 is formed such that it is closer to the surface of the semiconductor substrate S than the bit lines in a region which adjoins the intermediate dielectric 2. The insulation structure 4 has, between adjacent bit lines 1, a gap which reaches an underside of the bit lines 1 and is filled with a conductive shielding device 5 which additionally adjoins a top side of the insulation structure 4 above the bit lines 1, with the result that a continuously formed conductive shielding device 5 is present between adjacent bit lines 1 and above the bit lines 1. The shielding device 5 is additionally covered, on a surface which does not adjoin the insulation structure 4, by a covering layer 6, for example a polysilicon layer. The conductive shielding device 5 thus results in a reduction in the bit line-bit line coupling since such coupling is shielded via the insulation structure 4 which is formed between adjacent bit lines 1 and via a dielectric which is formed above the bit lines.

FIG. 1B illustrates a plan view of the first embodiment (illustrated in FIG. 1A) of a semiconductor memory apparatus having a conductive shielding device 5 according to the invention. The conductive shielding device 5, which adjoins the protective layer 3 and the insulation structure 4, and the covering layer 6 have been removed outside a cell array Z, i.e. in a region which is not a cell array NZ, for example a support region.

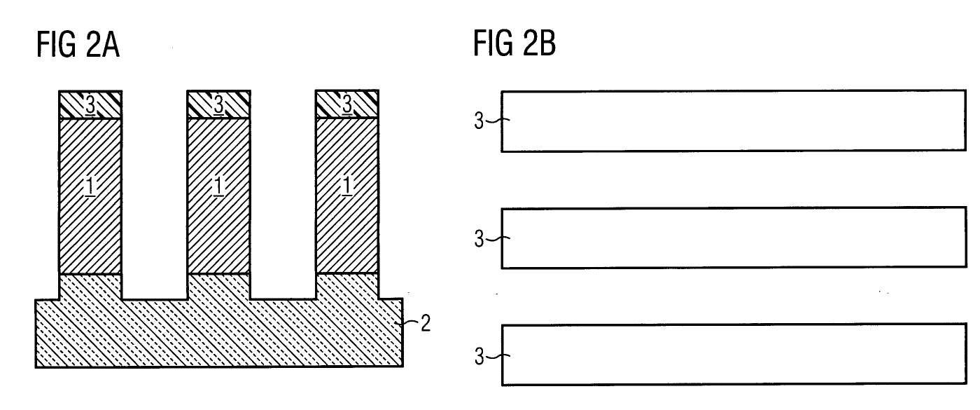

FIG. 2A illustrates a diagrammatic cross-sectional view of the first embodiment of a semiconductor memory apparatus according to the invention at the beginning of a process sequence for forming the conductive shielding device. The figure shows the first embodiment of the semiconductor memory apparatus according to the invention after the protective layer 3 has been patterned and a metal which forms the bit lines 1 has been etched with undercutting into the intermediate dielectric 2. Reactive ion etching (RIE), for example, is used as the etching process.

FIG. 2B illustrates a plan view of the cross section (diagrammatically illustrated in FIG. 2A) of the first embodiment of a semiconductor memory apparatus after the etching process for defining the bit lines 1. The protective layer 3 which is formed above the bit lines 1, which run parallel to one another, is illustrated.

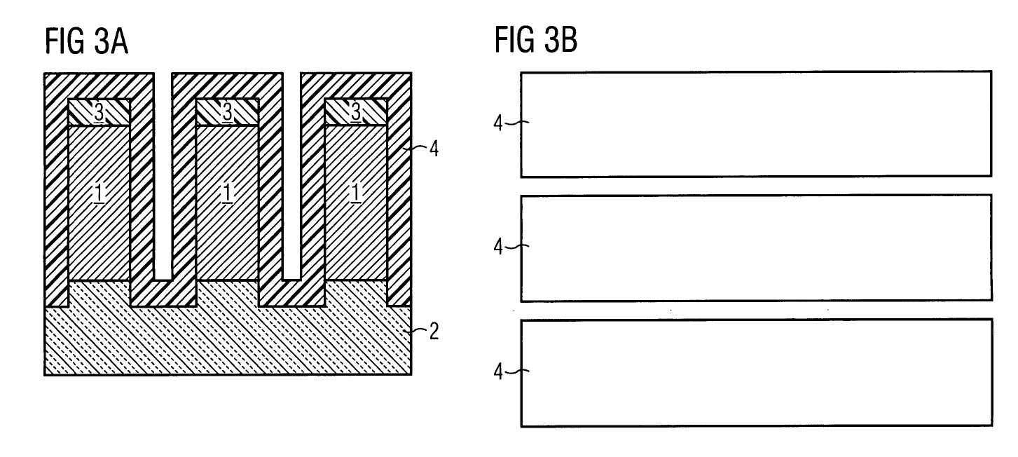

FIG. 3A illustrates a process stage of the first embodiment of a semiconductor memory apparatus according to the invention after the insulation structure 4 has been applied. The insulation structure 4, for example in the form of a TEOS layer, covers the protective layer 3, the bit lines 1 and that part of the intermediate dielectric 2 which has been exposed as a result of the bit lines 1 being etched. A part of the insulation structure 4, which is formed between adjacent bit lines 1, has a gap which is used, in subsequent processes, to form the conductive shielding device. The gap is essentially formed such that it is as deep as the bit lines 1.

FIG. 3B illustrates a plan view of the diagrammatic cross-sectional view (illustrated in FIG. 3A) of the first embodiment. Gaps for forming the conductive shielding device are illustrated between adjacent strips of the insulation structure 4.

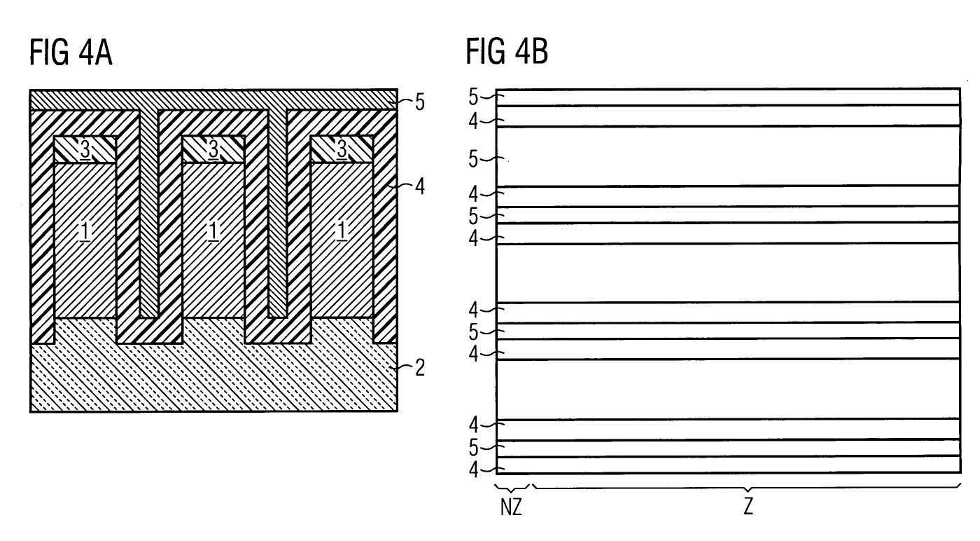

After the insulation structure 4 has been formed, the conductive shielding device 5 is produced as illustrated in the diagrammatic cross-sectional view in FIG. 4A. The shielding device is deposited, for example, in the form of a conductive material or in the form of a combination of a plurality of conductive materials, for instance in the form of a TiN layer. The conductive shielding device both fills the gaps which are formed between adjacent bit lines 1 in the insulation structure 4 and additionally covers both the cell array Z and the region which is not a cell array NZ on a top side of the insulation structure 4 (Z and NZ are illustrated only in part in FIG. 4B and subsequent figures).

Covering the cell array Z and the region which is not a cell array NZ with the conductive shielding device 5 is illustrated in FIG. 4B as uniform coverage in the plan view of the first embodiment of a semiconductor memory apparatus having a conductive shielding device according to the invention.

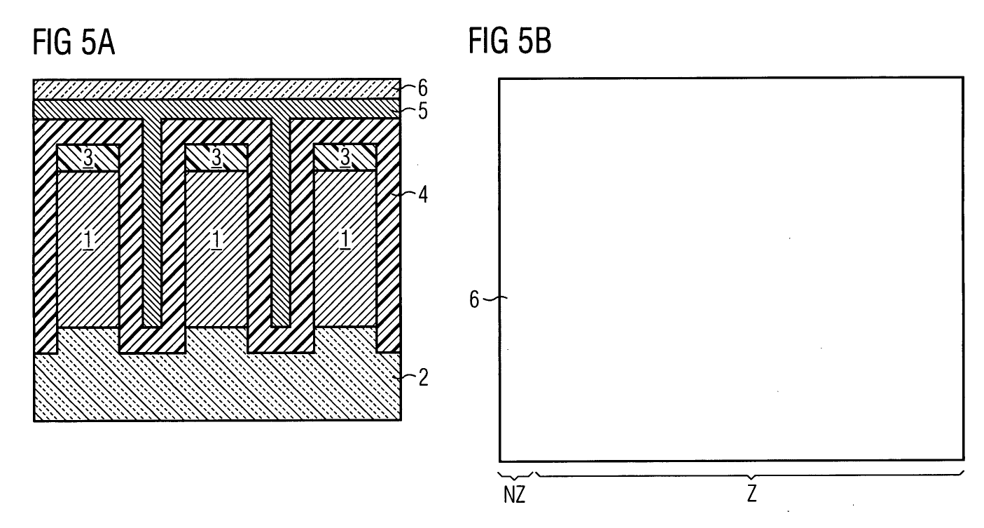

After the conductive shielding device 5 has been formed, a covering layer 6 is produced on the latter as illustrated in the diagrammatic cross-sectional view in FIG. 5A. The covering layer 6 may be applied, for example, in the form of a polysilicon layer, in particular in the form of a doped polysilicon layer, using a suitable method, for instance a CVD method, in particular an LPCVD method.

The covering layer 6 illustrated in the plan view in FIG. 5B covers both the cell array Z and the region which is not a cell array NZ.

Forming the covering layer 6 is particularly advantageous if, when applying the conductive shielding device 5, a residual gap is retained between adjacent bit lines, i.e. the conductive shielding device 5 does not completely fill the gap between adjacent bit lines 1 within the insulation structure 4. The cause of the occurrence of the residual gap may be, for example, fluctuations in the critical dimensions CD when patterning the bit lines 1.

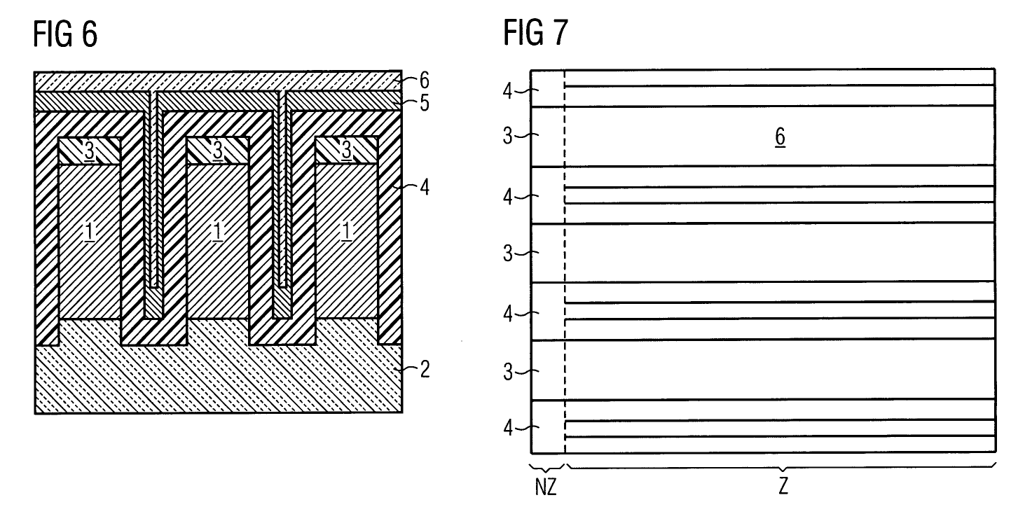

FIG. 6 illustrates a diagrammatic cross-sectional view of the first embodiment of a semiconductor memory apparatus having a residual gap in the region of the conductive shielding device 5 which is formed between adjacent bit lines 1. Applying the covering layer 6 fills the residual gap and process fluctuations such as CD fluctuations may be compensated for.

FIG. 7 illustrates a plan view of the first embodiment of a semiconductor memory apparatus after the covering layer 6 and the conductive shielding device 5 have been removed from the region which is not a cell array NZ and is illustrated merely in part, for example a support region having evaluation and drive circuit blocks of the cell array Z. For the purpose of removal, a protective mask, for instance, is applied to the covering layer 6 and is patterned and both the covering layer 6 and the conductive shielding device 5 are then removed in the region which is not a cell array NZ using isotropic etching. Parts of the insulation structure 4 or the entire insulation structure may likewise be removed during etching.

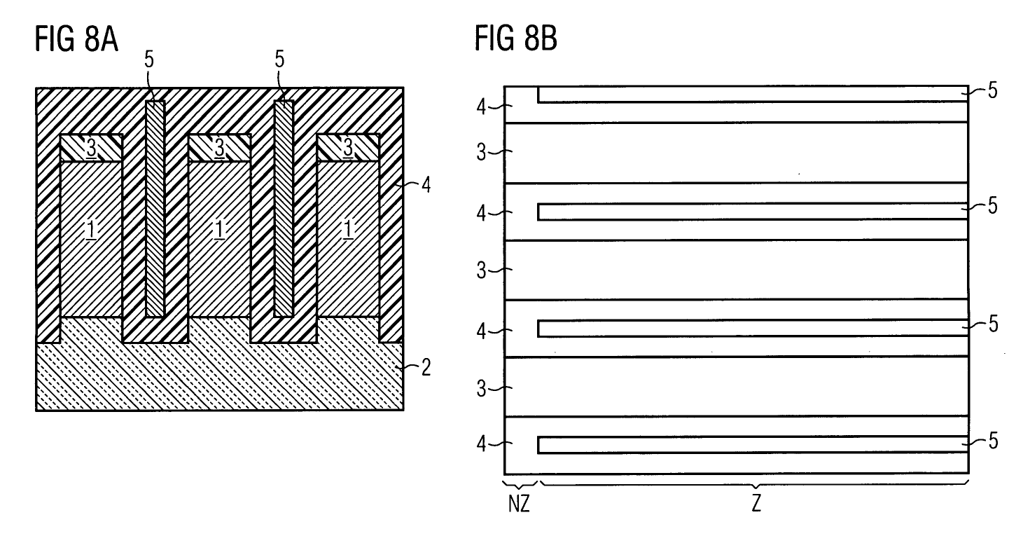

FIG. 8A illustrates a cross-sectional view of a second embodiment of a semiconductor memory apparatus. In a manner corresponding to the formation of the first embodiment which is illustrated in FIGS. 1A to 7 and was described further above, the process steps up to and including the formation of the conductive shielding device are carried out (corresponding to the cross-sectional view illustrated in FIG. 4A). However, unlike the formation of the first embodiment, the conductive shielding device 5 is etched back as far as the insulation structure 4 which is formed above the bit lines 1, with the result that the insulation structure fills only the gaps formed between adjacent bit lines 1 within the insulation structure 4. The insulation structure 4 is then thickened so that it likewise encompasses a top side of the conductive shielding device 5.

FIG. 8B illustrates a plan view of the diagrammatic cross-sectional view of the second embodiment illustrated in FIG. 8A. The conductive shielding device 5 has been removed in the region which is not a cell array NZ.

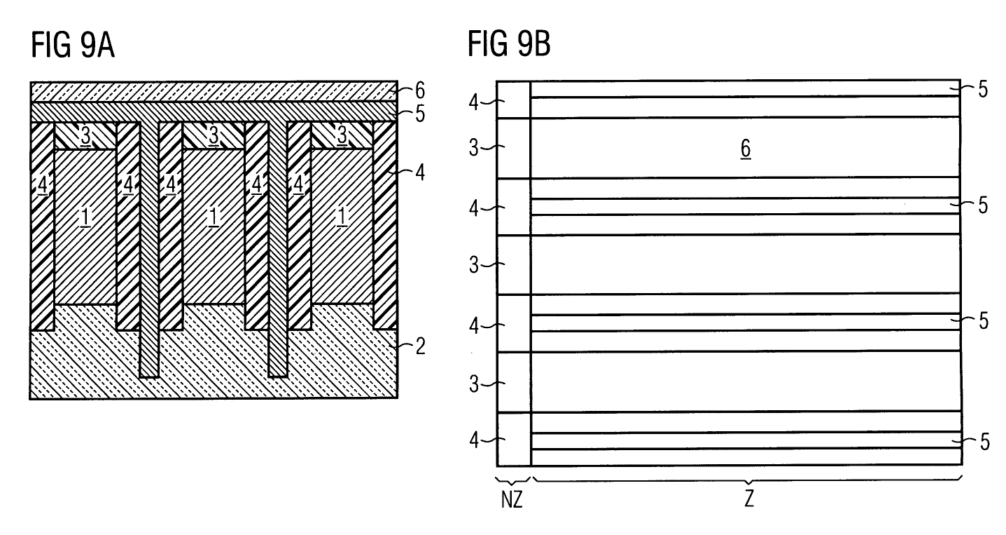

FIG. 9A illustrates a diagrammatic cross-sectional view of a third embodiment of a semiconductor memory apparatus according to the invention. In contrast to the first and second embodiments explained further above with the aid of FIGS. 1A to 8B, the conductive shielding layer 5 extends further into the intermediate dielectric 2 in the third embodiment. This reduces, in particular, part of the bit line-bit line coupling caused by the intermediate dielectric 2 formed below the bit lines 1. An opening which reaches further into the intermediate dielectric 2 than the insulation structure 4 may be achieved, for example, by means of extended etching of the insulation structure 4 when forming spacers. It shall be mentioned at this juncture that, in this case, the protective layer 3 which is formed on the bit lines 1 is likewise partially removed, namely approximately from that point in time from which etching into the intermediate dielectric 2 is carried out. In order to avoid completely removing the protective layer 3 when etching the intermediate dielectric 2 and in order to expose the bit lines 1, the protective layer 3 may be of thickened design so that it continues to cover the bit lines 1 after etching into the intermediate dielectric 2 has been carried out. It is likewise possible to form the protective layer 3 as a material which is not attacked when etching the intermediate dielectric 2 with high selectivity. The formation of the conductive shielding device 5, which is effected after the insulation structure 4 has been etched, results in both the gap which is formed between adjacent bit lines 1 within the insulation structure 4 and the gap which is formed within the intermediate dielectric 2 being filled with the conductive shielding device 5. The latter is additionally formed on the protective layer 3 (which is formed above the bit lines 1) and such that it extensively covers the cell array Z.

FIG. 9B illustrates a plan view of the diagrammatic cross-sectional view (illustrated in FIG. 9A) of the third embodiment of a semiconductor memory apparatus. The conductive shielding device 5 has been removed in the region which is not a cell array NZ.

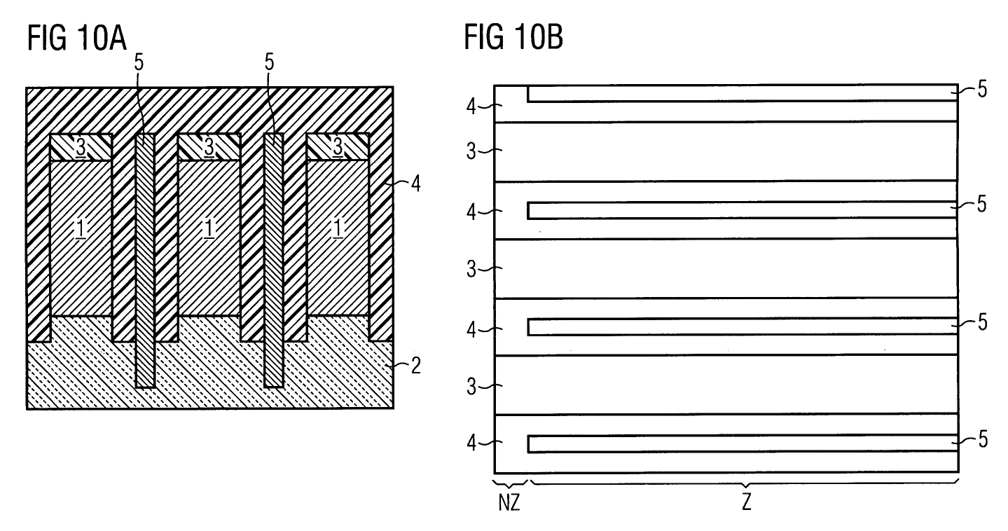

FIG. 10A illustrates a diagrammatic cross-sectional view of a fourth embodiment of a semiconductor memory apparatus. As in the third embodiment illustrated in FIG. 9A, the conductive shielding device reaches, between adjacent bit lines 1, further into the intermediate dielectric 2 than the insulation structure 4 in the fourth embodiment too. Unlike the cross-sectional view (illustrated in FIG. 9A) of the third embodiment, the conductive shielding device 5 in the fourth embodiment is not formed above the protective layer 3 in the cell array Z but rather merely in the gap between adjacent bit lines 1 in order to reduce, in particular, lateral bit line-bit line coupling.

FIG. 10B illustrates a plan view of the diagrammatic cross-sectional view (illustrated in FIG. 10A) of the fourth embodiment of a semiconductor memory apparatus. The conductive shielding device 5 has been removed in the region which is not a cell array NZ.

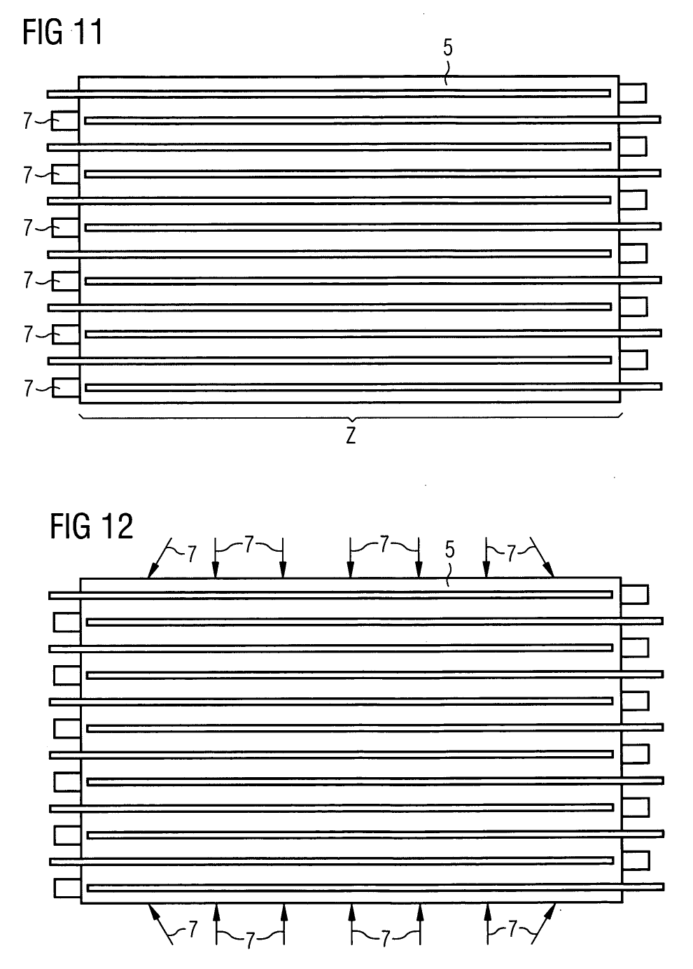

FIG. 11 illustrates a diagrammatic plan view of a cell array Z having a conductive shielding device 5. In order to contact-connect the conductive shielding device 5 for the purpose of connecting it to a preferably constant potential, for instance VBLEQ, use is made of contact regions 7 of the conductive shielding device 5, the contact regions being formed at the edge of the cell array Z. The conductive shielding device 5 may be mechanically contact-connected, for example, with the aid of contact plugs which are used to contact-connect the bit lines.

FIG. 12 illustrates the diagrammatic plan view (illustrated in FIG. 11) of the cell array Z having a conductive shielding device 5. The conductive shielding device 5 is contact-connected via a contact region 7 of the cell array Z on the underside and/or the top side of the latter.

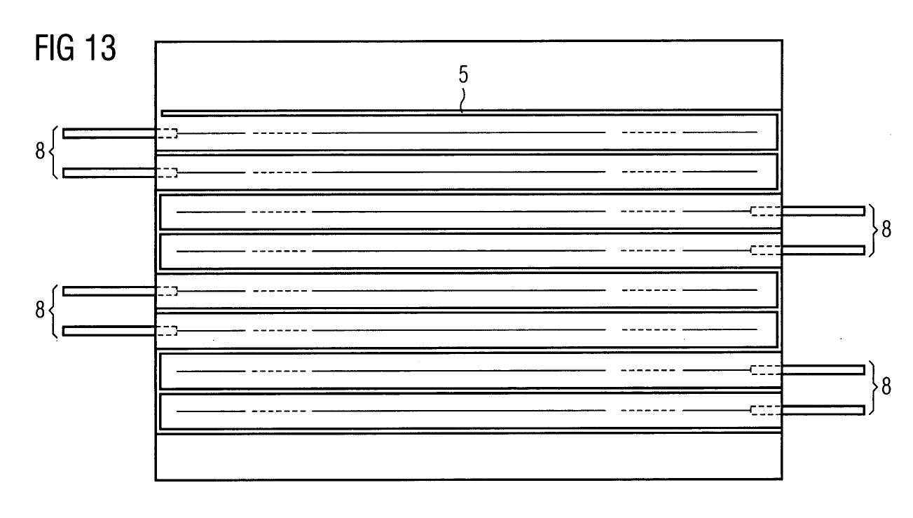

FIG. 13 illustrates a diagrammatic plan view of a cell array Z of a semiconductor memory apparatus having a conductive shielding device 5. The conductive shielding device 5 which is formed between adjacent bit lines 1 is designed to be continuous in the cell array Z, the bit lines 1 running parallel to one another without twisting using a bit line twist. Avoiding the bit line twist results in a saving in the chip area required for this and this saving is approximately 4-5% of the area of the cell array Z, it being possible for deviations from this value to occur depending on the design of the bit line twist. However, saving the chip area by avoiding the bit line twist in FIG. 13 does not result in a reduced charge retention time since the conductive shielding device 5 contributes to the increase in the charge retention time.

Although specific embodiments have been illustrated and described herein, it will be appreciated by those of ordinary skill in the art that a variety of alternate and/or equivalent implementations may be substituted for the specific embodiments illustrated and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor memory apparatus comprising:
a plurality of bit lines which are arranged next to one another and run above a semiconductor substrate; and
an insulation structure which at least laterally adjoins the bit lines, which comprises a respective conductive shielding device which is formed between two bit lines arranged next to one another, is at a distance from the bit lines and at least partially adjoins the insulation structure.

2. The semiconductor memory apparatus as claimed in claim 1, comprising wherein the conductive shielding device has a plurality of shielding elements.

3. The semiconductor memory apparatus as claimed in claims 1, comprising wherein the conductive shielding device has at least one metal and/or at least one doped semiconductor material.

4. The semiconductor memory apparatus as claimed in claim 1, comprising wherein a protective layer is formed on each of the bit lines.

5. The semiconductor memory apparatus as claimed in claim 1, comprising wherein the conductive shielding device is formed such that it is at least as far away from the semiconductor substrate as the bit lines.

6. The semiconductor memory apparatus as claimed in claim 1, comprising wherein the conductive shielding device covers a cell array above the bit lines.

7. The semiconductor memory apparatus as claimed in claim 1, comprising wherein the insulation structure adjoins a top side of the conductive shielding device.

8. The semiconductor memory apparatus as claimed in claim 1, comprising wherein the conductive shielding device can be electrically contact-connected in an edge region of a cell array.

9. A semiconductor memory apparatus comprising:
a plurality of bit lines which are arranged next to one another and run above a semiconductor substrate; and
an insulation structure which at least laterally adjoins the bit lines, which comprises a respective conductive shielding device which is formed between two bit lines arranged next to one another, is at a distance from the bit lines and at least partially adjoins the insulation structure, wherein the conductive shielding device is formed such that it is at least as close to the semiconductor substrate as the bit lines in an intermediate dielectric which is below the bit lines.

10. The semiconductor memory apparatus as claimed in claim 9, comprising wherein the insulation structure is formed such that it is closer to the semiconductor substrate than the bit lines.

11. The semiconductor memory apparatus as claimed in claim 10, comprising wherein the insulation structure adjoins an underside of the conductive shielding device.

12. The semiconductor memory apparatus as claimed in claim 11, comprising wherein the insulation structure is formed contiguously in a cell array.

13. The semiconductor memory apparatus as claimed in claim 12, comprising wherein a protective layer is formed on each of the bit lines.

14. A method for producing a conductive shielding device for reducing the capacitive coupling between adjacent bit lines of a memory apparatus, the method comprising:
applying a metal layer to a preprocessed semiconductor substrate;
applying a protective layer to the metal layer;
patterning the protective layer in order to define the bit lines which are to be formed in the metal layer;
forming the bit lines by removing the metal layer in regions which are not covered by the protective layer;
applying an insulation structure to the protective layer, the bit lines and a region of the intermediate dielectric, which is exposed between the bit lines;
applying a conductive shielding device to the insulation structure;
applying a protective mask to the conductive shielding device in the cell array; and
removing the conductive shielding device outside the cell array in the region which is not a cell array.

15. The method as claimed in claim 14, comprising wherein after the bit lines have been formed and before the conductive shielding device is applied, a part of an intermediate dielectric which is formed below the metal layer and on the semiconductor substrate is removed.

16. The method as claimed in claim 14, comprising wherein after the insulation structure has been applied and before the conductive shielding device is applied,
extended spacer etching is effected in order to remove a part of the insulation structure, which is above the protective layer, and parts of a base region of the insulation structure, which adjoins the intermediate dielectric, and in order to form the insulation structure as a spacer; and
a part of the intermediate dielectric below the base region additionally being removed.

17. The method as claimed in claim 14, comprising wherein after the conductive shielding device has been applied and before the protective mask is applied, a covering layer is applied to the conductive shielding device.

18. The method as claimed in claim 14, comprising wherein the conductive shielding device is partially removed, a part of the conductive shielding device, which is formed between the bit lines , being retained and a part of the conductive shielding device , which covers the cell array, being lost.

19. The method as claimed in claim 14, comprising:
applying an insulation covering after the conductive shielding device has been removed.

20. A method for producing a conductive shielding device for reducing the capacitive coupling between adjacent bit lines of a memory apparatus, the method comprising:
applying a metal layer to a preprocessed semiconductor substrate;
applying a protective layer to the metal layer;
patterning the protective layer in order to define the bit lines which are to be formed in the metal layer;
forming the bit lines by removing the metal layer in regions which are not covered by the protective layer;
applying an insulation structure to the protective layer, the bit lines and a region of the intermediate dielectric, which is exposed between the bit lines;
applying a conductive shielding device to the insulation structure;
applying a protective mask to the conductive shielding device in the cell array; and
removing the conductive shielding device outside the cell array in the region which is not a cell array;
wherein after the bit lines have been formed and before the conductive shielding device is applied, a part of an intermediate dielectric which is formed below the metal layer and on the semiconductor substrate is removed; and
wherein after the insulation structure has been applied and before the conductive shielding device is applied,
extended spacer etching is effected in order to remove a part of the insulation structure, which is above the protective layer, and parts of a base region of the insulation structure, which adjoins the intermediate dielectric, and in order to form the insulation structure as a spacer; and
a part of the intermediate dielectric below the base region additionally being removed.

21. The method as claimed in claim 20, comprising wherein after the conductive shielding device has been applied and before the protective mask is applied, a covering layer is applied to the conductive shielding device.

22. The method as claimed in claim 21, comprising wherein the conductive shielding device is partially removed, a part of the conductive shielding device, which is formed between the bit lines , being retained and a part of the conductive shielding device, which covers the cell array, being lost.

23. The method as claimed in claim 22, comprising:
applying an insulation covering after the conductive shielding device has been removed.

24. A semiconductor memory apparatus comprising:
a plurality of bit lines which are arranged next to one another and run above a semiconductor substrate; and
means for providing an insulation structure which at least laterally adjoins the bit lines, which comprises a respective conductive shielding device which is formed between two bit lines arranged next to one another, is at a distance from the bit lines and at least partially adjoins the insulation structure means.
